(19) United States
(12) Patent Application Publication
(10) Pub. No.: US 2024/0210166 A1
(43) Pub. Date: Jun. 27, 2024

(54) METHOD FOR MONITORING PERFORMANCE OF ECCENTRICITY CORRECTION UNIT AND SUBSTRATE TREATING APPARATUS FOR PERFORMING METHOD

(71) Applicant: SEMES CO., LTD., cheonan-si (KR)

(72) Inventors: In Ki JUNG, Gyeonggi-do (KR); Jeong Hyup YU, Gyeonggi-do (KR); Young Joon HAN, Chungcheongnam-do (KR); Sung Bum PARK, Chungcheongnam-do (KR)

(21) Appl. No.: 18/385,909

(22) Filed: Nov. 1, 2023

(30) Foreign Application Priority Data
Dec. 21, 2022 (KR) 10-2022-0180061

(51) Int. Cl. G01B 11/24

(52) U.S. Cl. CPC G01B 11/24

(57) ABSTRACT

A method for monitoring performance of an eccentricity correction unit, the method includes a first operation of measuring eccentricity of a substrate mounted on a support unit and storing an amount of eccentricity correction corrected by the eccentricity correction unit such that measured eccentricity of the substrate is within a preset allowable eccentricity value, and a second operation of monitoring, based on the stored amount of eccentricity correction, performance degradation of the eccentricity correction unit.

### CROSS-REFERENCE TO RELATED APPLICATION (S)

This application claims benefit of priority to Korean Patent Application No. 10-2022-0180061 filed on Dec. 21, 2022 in the Korean Intellectual Property Office, the disclosure of which is incorporated herein by reference in its entirety.

### BACKGROUND

### 1. Field

The present disclosure relates to a method for monitoring performance of an eccentricity correction unit and a substrate treatment apparatus for performing the method.

### 2. Description of Related Art

In general, in order to manufacture semiconductor devices, various processes such as a photo process, an etching process, an ion implantation process, and a deposition process are performed. In each process, liquid is supplied to a substrate to perform a predetermined treatment.

In various processes for treating a substrate, the substrate needs to be mounted in a correct position on a support unit. For example, in a liquid treatment process in which liquid is supplied to a substrate, when the substrate is disposed in a position offset from the correct position on the support unit, a spotting point of the liquid supplied to the substrate is shifted. In this case, the liquid is not uniformly applied to the substrate or is not targeted and supplied accurately to a specific point on the substrate, thereby preventing uniform liquid treatment of the substrate. In addition, in a process of treating a substrate using plasma, when the substrate is mounted in a position offset from the correct position on the support unit, a sheath of the plasma formed on an upper side of the substrate may be changed to prevent uniform plasma treatment of the substrate. In particular, in a process of etching a thin film or impurities formed on an edge region of the substrate, when the substrate is not mounted in the correct position on the support unit, it may be difficult to uniformly etch the edge region of the substrate, resulting in a decrease in yield of the treated substrate.

In addition, when the substrate is not in the correct position on the support unit, there may be various causes such as the substrate deviating from the correct position, or the support unit being misaligned. When the cause of the substrate not being mounted in the correct position on the support unit is an irreparable cause, each process may not be smoothly performed even when the substrate is corrected to be in the correct position, resulting in a decrease in yield of the substrate. Accordingly, continuous monitoring needs to be performed to prevent performance degradation beyond a certain level.

### SUMMARY

An aspect of the present disclosure provides a method for monitoring performance of an eccentricity correction unit in which a substrate is uniformly treated, and a situation of eccentricity correction of the substrate is continuously monitored to predict a situation and cause of occurrence of performance degradation beyond a certain level, and a substrate treatment apparatus for performing the method.

According to an aspect of the present disclosure, there is provided a method for monitoring performance of an eccentricity correction unit, the method including a first operation of measuring eccentricity of a substrate mounted on a support unit and storing an amount of eccentricity correction corrected by the eccentricity correction unit such that measured eccentricity of the substrate is within a preset allowable eccentricity value and a second operation of monitoring, based on the stored amount of eccentricity correction, performance degradation of the eccentricity correction unit.

According to another aspect of the present disclosure, there is provided a substrate treatment apparatus including a support unit configured to support a substrate, a liquid supply unit configured to supply liquid to the substrate supported by the support unit, a treatment container configured to surround the substrate supported by the support unit, an eccentricity correction unit configured to measure and correct eccentricity of the substrate supported by the support unit, a storage unit configured to store an amount of eccentricity correction corrected by the eccentricity correction unit, and a control unit configured to monitor, based on the stored amount of eccentricity correction, performance degradation of the eccentricity correction unit, and to control the substrate treatment apparatus depending on a monitoring result.

According to another aspect of the present disclosure, there is provided a substrate treatment apparatus including a housing having an internal space, a chuck positioned in the internal space, the chuck configured to support and rotate a substrate, a liquid supply unit configured to supply liquid to the substrate supported by the chuck to etch an edge region of the substrate, a treatment container configured to surround the substrate supported by the chuck, an elevation unit configured to raise and lower the treatment container, an eccentricity correction unit in contact with a plurality of points of a side end of the substrate supported by the chuck, the eccentricity correction unit configured to correct eccentricity of the substrate supported by the chuck, a storage unit configured to store an amount of eccentricity correction corrected by the eccentricity correction unit, and an amount of misalignment of the support unit calculated by adding the amount of eccentricity correction and a degree of corrected eccentricity of the substrate, and a control unit configured to monitor, based on an amount of change over time in the stored amount of eccentricity correction or amount of misalignment, performance degradation of the eccentricity correction unit, and to control the substrate treatment apparatus depending on a monitoring result. The eccentricity correction unit may include a first correction unit in contact with one point and another point, sharing one axis on a horizontal plane, among the points, and a second correction unit in contact with still another point belonging to another axis, different from the one axis. The second correction unit may include a displacement measurement unit configured to measure a degree of eccentricity at different points of the rotating substrate, and an elastic portion in contact with the side ends of the substrate, the elastic portion configured to provide elastic force. The control unit may be configured to interlock the substrate treatment apparatus, when the calculated amount of misalignment is greater than or equal to a preset allowable amount of misalignment or the amount of eccentricity correction is greater than or equal to an allowable amount of eccentricity correction.

According to an example embodiment of the present disclosure, a substrate may be uniformly treated, and a degree of eccentricity of the substrate or an amount of misalignment of a support unit may be accurately measured and corrected.

In addition, according to an example embodiment of the present disclosure, performance degradation of an eccentricity correction unit or a cause of performance degradation may be predicted through a change over time in a stored amount of eccentricity correction. When performance degradation occurs, a substrate treatment apparatus may be interlocked to identify an exact cause of performance degradation, without affecting substrate yield.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic cross-sectional view of a process chamber according to an example embodiment of the present disclosure;

FIG. 2 is a top cross-sectional view of a process chamber in which an eccentricity correction unit is installed according to an example embodiment of the present disclosure;

FIG. 3 illustrates a portion of an eccentricity correction unit performing an eccentricity measurement operation according to an example embodiment of the present disclosure;

FIG. 4 is a flowchart illustrating a method for monitoring performance of an eccentricity correction unit according to an example embodiment of the present disclosure;

FIGS. 5 to 7 are graphs illustrating a change over time in an amount of eccentricity correction of an eccentricity correction unit according to an example embodiment of the present disclosure;

FIG. 8 illustrates a specific process of a method for monitoring performance of an eccentricity correction unit according to an example embodiment of the present disclosure; and

FIG. 9 is a top cross-sectional view of a process chamber in which an eccentricity correction unit is installed according to another example embodiment of the present disclosure.

### DETAILED DESCRIPTION

Hereinafter, preferred example embodiments will be described in detail, such that the disclosure could be easily carried out. In describing example embodiments of the present disclosure, when it is determined that a detailed description of a known technology related to the present disclosure may unnecessarily obscure the gist of the present disclosure, a detailed description thereof will be omitted. In addition, the same reference numerals are used throughout the drawings with respect to components having similar functions and actions. In addition, in the present specification, terms such as “upper,” “upper portion,” “upper surface,” “lower,” “lower portion,” “lower surface,” and “side surface” are based on the drawings, may vary depending on a direction in which an element or component is actually arranged.

When it is mentioned that one component is “connected” or “accessed” to another component, it may be understood that the one component is directly connected or accessed to another component or that still other component is interposed between the two components. In addition, it should be noted that if it is described in the specification that one component is “directly connected” or “directly joined” to another component, still other component may not be present therebetween. In addition, it will be understood that “comprises” and/or “comprising” specify the presence of stated features, integers, steps, operations, elements, components or a combination thereof, but do not preclude the presence or addition of one or more other features, integers, steps, operations, elements, components, and/or groups thereof.

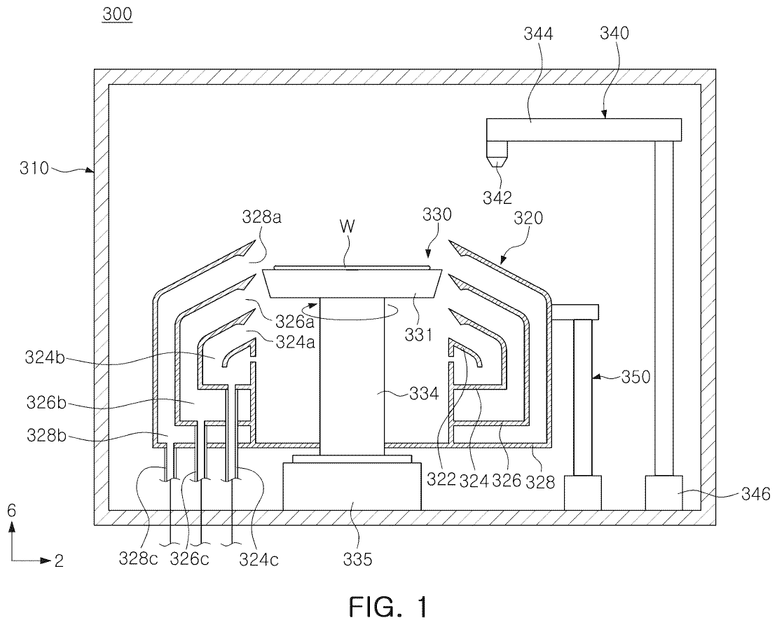

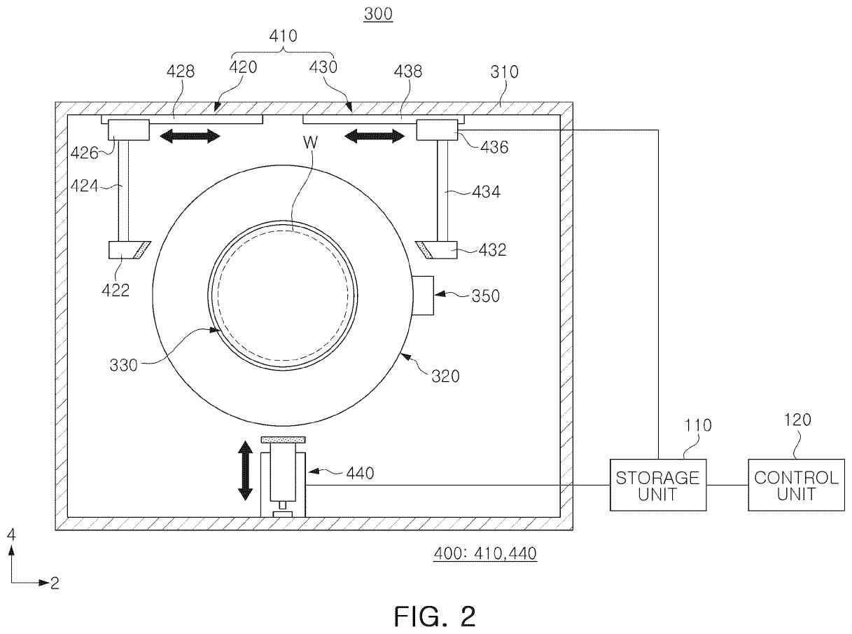

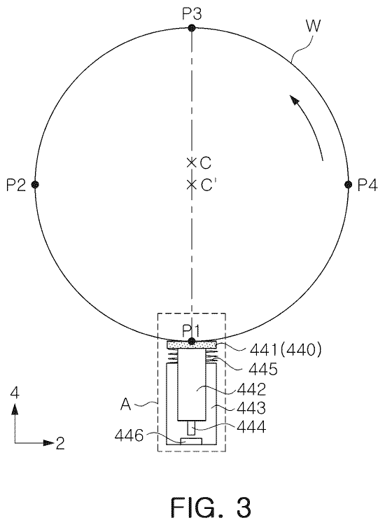

FIG. 1 is a schematic cross-sectional view of a process chamber according to an example embodiment of the present disclosure. FIGS. 2 and 3 are top cross-sectional views of a process chamber in which an eccentricity correction unit is installed according to an example embodiment of the present disclosure.

The process chamber 300 may include a housing 310, a treatment container 320, a support unit 330, a liquid supply unit 340, an elevation unit 350, and an eccentricity correction unit 400.

In FIG. 1, the eccentricity correction unit 400 according to an example embodiment is omitted for ease of understanding. In FIG. 2, the liquid supply unit 340 according to an example embodiment is omitted for ease of understanding. Hereinafter, the housing 310, the treatment container 320, the support unit 330, the liquid supply unit 340, and the elevation unit 350 according to an example embodiment will be described with reference to FIG. 1, and the eccentricity correction unit 400 according to an example embodiment will be described with reference to FIG. 2.

The housing 310 may have a substantially rectangular parallelepiped shape. The housing 310 may have an internal space. In the internal space, the treatment container 320, the support unit 330, the liquid supply unit 340, the elevation unit 350, and the eccentricity correction unit 400 (see FIG. 2) to be described below may be positioned. An entrance/exit opening (not illustrated) may be formed in a sidewall of the housing 310. The entrance/exit opening (not illustrated) may function as a passage through which the substrate W enters or exits the housing 310. Although not illustrated, the bottom of the housing 310 may have an exhaust hole for exhausting atmosphere of the internal space.

The treatment container 320 may be a bowl having an open upper portion. The interior of the treatment container 320 may function as a space in the substrate W is treated. The treatment container 320 may be disposed on the outside of the substrate W, supported by the support unit 330 to be described below, to surround the substrate W.

In an example embodiment, the treatment container 320 may have a guide wall 322 and a plurality of collecting containers 324, 326, and 328. Each of the guide wall 322 and the collecting containers 324, 326, and 328 may have a ring shape, surrounding the support unit 330. The collecting containers 324, 326, and 328 may respectively have collecting spaces 324b, 326b, and 328b for separating and collecting different liquids, among liquids used to treat the substrate W. When a process of supplying liquid to the substrate W to etch an edge region of the substrate W is performed, liquid, scattered by rotation of the substrate W, may flow into the collecting spaces 324b, 326b, and 328b through inlets 324a, 326a, and 328a of the collecting containers 324, 326, and 328.

According to an example embodiment, the treatment container 320 may include a first collecting container 324, a second collecting container 326, and a third collecting container 328. The first collecting container 324 may be disposed to surround the support unit 330, the second collecting container 326 may be disposed to surround the first collecting container 324, and the third collecting container 328 may be disposed to surround the second collecting container 326. A first inlet 324a through liquid flows into a collecting space 324b of the first collecting container 324 may be positioned below a second inlet 326a through liquid flows into a collecting space 326b of the second collecting container 326. In addition, the second inlet 326a may be positioned below a third inlet 328a through which liquid flows into a collecting space 328b of the third collecting container 328. Liquid discharge pipes 324c, 326c, and 328c for discharging liquid may be respectively coupled to the collecting containers 324, 326, and 328. The liquid, discharged through the liquid discharge pipes 324c, 326c, and 328c, may be reused using an external regeneration system (not illustrated).

The number of collecting containers described above may vary depending on the number of liquids used and the number of liquids to be collected or discarded. Although not illustrated, an exhaust line for exhausting fume and gas may be connected to the bottom of the treatment container 320.

The support unit 330 may support and rotate the substrate W. The support unit 330 may include a chuck 331 and a spin axis 334. An upper surface of the chuck 331 may have a substantially circular shape. In addition, the upper surface of the chuck 331 may have a diameter greater than that of the substrate W. The substrate W may be mounted on the upper surface of the chuck 331. Accordingly, the chuck 331 may support the substrate W. The chuck 331 may mechanically support the substrate W using a support pin (not illustrated) or the like. However, the present disclosure is not limited thereto, and the chuck 331 may support the substrate W using a vacuum suction method.

The spin axis 334 may have a longitudinal direction, parallel to a third direction 6. One end of the spin axis 334 may be coupled to the chuck 331, and the other end of the spin axis 334 may be coupled to an axis driver 335. More specifically, one end of the spin axis 334 may be coupled to a lower end of the chuck 331, and the other end of the spin axis 334 may be inserted into a hollow formed in a bottom central portion of the treatment container 320 and be coupled to the axis driver 335. The axis driver 335 may rotate the spin axis 334 using the longitudinal direction of the spin axis 334 as a rotation axis. Accordingly, the chuck 331, coupled to the spin axis 334, may also rotate and the substrate W, mounted on the upper surface of the chuck 331, may also rotate. The axis driver 335 may be one of known motors transmitting rotational force. In addition, the axis driver 335 may raise and lower the spin axis 334 in a direction, parallel to the third direction 6.

The liquid supply unit 340 may supply liquid to the substrate W, supported by the support unit 330. The liquid supply unit 340 may include a nozzle 342. The liquid according to an example embodiment may be an etchant removing a thin film or impurities formed on the substrate W. In addition, the liquid according to an example embodiment may be etch-blocking liquid for diluting liquid removing impurities or a thin film formed on the substrate W. According to an example embodiment, the etchant may include an acid such as hydrofluoric acid (HF) or phosphoric acid (P₂O₅). According to an example embodiment, the etch-blocking liquid may be pure. However, the present disclosure is not limited thereto, and the liquid according to an example embodiment may include various types of liquids not exemplified above. That is, the liquid according to an example embodiment may include all various types of liquids used when the substrate W is treated.

The nozzle 342 may be coupled to an arm 344. Accordingly, the nozzle 342 may be supported by the arm 344. The arm 344 may have a substantially “L” shape. The arm 344 may be coupled to an arm driver 346. The arm driver 346 may allow swing movement or straight movement of the arm 344. Accordingly, the nozzle 342 may be moved between a standby position and a liquid supply position by the arm driver 346.

The standby position may be a position in which the nozzle 342 stands by when liquid is not supplied to the substrate W. The liquid supply position may be a position in which the nozzle 342 supplies liquid onto the substrate W. For example, when viewed from above, the nozzle 342 may be positioned to overlap the substrate W in the liquid supply position. More specifically, when an etchant is supplied to the substrate W, the nozzle 342 may be positioned to correspond to an upper side of the edge region of the substrate W. In addition, when the etch-blocking liquid is supplied is onto the substrate W, the nozzle 342 may be positioned to correspond to an upper side of a central region of the substrate W.

The elevation unit 350 may change a position of the treatment container 320. For example, the elevation unit 350 may raise and lower the treatment container 320 in a direction, parallel to the third direction 6. The elevation unit 350 may be one of known motors transmitting driving force. Vertical movement of the treatment container 320 may change a relative height between the treatment container 320 and the substrate W supported by the support unit 330. Accordingly, depending on a type and composition ratio of liquid supplied to the substrate W, the collecting containers 324, 326, and 328 may separate and collect the liquid.

According to an example embodiment, when the substrate W is treated, the elevation unit 350 may move the treatment container 320 in an upward direction such that an upper end of the treatment container 320 is positioned to be higher than an upper end of the substrate W. In addition, when eccentricity of the substrate W is corrected after treatment of the substrate W is completed or before the substrate W is treated, the elevation unit 350 may move the treatment container 320 in a downward direction such that the upper end of the treatment container 320 is positioned to be lower than an upper end of the chuck 331.

The eccentricity correction unit 400 may change the position of the substrate W, mounted on the chuck 331. More specifically, the eccentricity correction unit 400 may correct eccentricity of the substrate W such that the center of the substrate W, mounted on the chuck 331, correspond to a central axis of the chuck 331. The eccentricity correction unit 400 according to an example embodiment may be in contact with a side end of the substrate W to change the position of the substrate W. A detailed mechanism thereof will be described below.

The eccentricity correction unit 400 may include a first correction unit 410 and a second correction unit 440. The first correction unit 410 and the second correction unit 440 may be installed on sidewalls of the housing 310, respectively. More specifically, the first correction unit 410 may be installed on one sidewall of the housing 310, and the second correction unit 440 may be installed on the other sidewall, opposing the one sidewall of the housing 310 on which the first correction unit 410 is installed. However, the present disclosure is not limited thereto, and installation positions of the first correction unit 410 and the second correction unit 440 may be changed on the sidewalls of the housing 310 in various manners.

The first correction unit 410 may be in contact with a plurality of points on the side end of the substrate W to change the position of the substrate W and determine the position of the substrate W. According to an example embodiment, when viewed from above, the first correction unit 410 may be in contact with two different points on the same axis to change the position of the substrate W. For example, two different points on the side end of the substrate W in contact with the first correction unit 410 may all be positioned on an X-axis. That is, the two different points on the side end of the substrate W in contact with the first correction unit 410 may share an X-axis on a horizontal plane.

The first correction unit 410 may include a first-first correction unit 420 and a first-second correction unit 430.

The first-first correction unit 420 may include a first-first contact portion 422, a first-first arm 424, a first-first drive unit 426, and a first-first rail 428.

The first-first contact portion 422 may be in contact with a first point on the side end of the substrate W to change the position of the substrate W. One surface of the first-first contact portion 422 may be formed to be inclined. The inclined surface of the first-first contact portion 422 may be a surface in contact with the substrate W. More specifically, the inclined surface of the first-first contact portion 422 may be inclined at an angle corresponding to an angle formed by a tangential direction of the substrate W. In addition, the inclined surface of the first-first contact portion 422 may be formed of a material such as poly-ether-ether-ketone (PEEK) filled with carbon. However, the present disclosure is not limited thereto, and the entire region of the first-first contact portion 422 may be formed of a material the same as PEEK.

The first-first arm 424 may be coupled to the first-first contact portion 422. The first-first arm 424 may have a longitudinal direction, parallel to a second direction 4. The first-first contact portion 422 may be coupled to one end of the first-first arm 424, and the first-first drive unit 426 may be coupled to the other end of the first-first arm 424. The first-first drive unit 426 may be one of known linear motors providing driving force to change a position of the first-first arm 424. In addition, the first-first rail 428 may be installed on one sidewall of the housing 310. The first-first rail 428 may have a longitudinal direction, parallel to a first direction 2. The first-first drive unit 426 may be mounted on the first-first rail 428 to move in a longitudinal direction (for example, the first direction 2) of the first-first rail 428. Accordingly, the first-first arm 424 and the first-first contact portion 422, coupled to the first-first drive unit 426, may also move in the first direction 2, and the first-first contact portion 422 may be in contact with the first point on the side end of the substrate W to change the position of the substrate W.

The first-second correction unit 430 may include a first-second contact portion 432, a first-second arm 434, a first-second drive unit 436, and a first-second rail 438.

The first-second contact portion 432 may be in contact with a second point on the side end of the substrate W to change the position of the substrate W. The second point according to an example embodiment may be a point sharing the same X-axis on the horizontal plane as the first point, as described above.

When viewed from above, the first-second contact portion 432, the first-second arm 434, the first-second drive unit 436, and the first-second rail 438 may be respectively symmetrical to the first-first contact portion 422, the first-first arm 424, the first-first drive unit 426, and the first-first rail 428 described above. That is, the first-second contact portion 432, the first-second arm 434, the first-second drive unit 436, and the first-second rail 438 may have a structure the same as or similar to that of the first-first contact portion 422, the first-first arm 424, the first-first drive unit 426, and the first-first rail 428. Accordingly, the following description will focus on the first-first correction unit 420, and a description of the first-second correction unit 430 will be omitted.

Components included in the above-described first-first correction unit 420 and first-second correction unit 430 may be disposed so as not to interfere with the liquid supply unit 340 illustrated in FIG. 2. In addition, the components included in the first-first correction unit 420 and the first-second correction unit 430 may be disposed in a position, not interfering with an entrance/exist opening (not illustrated) formed in the sidewall of the housing 310.

Unlike the above-described example, each of the first-first arm 424 and the first-second arm 434 may have a longitudinal direction, parallel to the first direction 2. In this case, the first-first rail 428 and the first-second rail 438 may not be provided, and the first-first drive unit 426 and the first-second drive unit 436, having a structure such as a cylinder, may respectively move the first-first arm 424 and the first-second arm 434 in a direction, parallel to the first direction 2.

The second correction unit 440 may be in contact with a point on the side end of the substrate W to change the position of the substrate W. According to an example embodiment, the second correction unit 440 may be in contact with one point on the side end of the substrate W included on one axis, different from another axis including a plurality of points, at which the first correction unit 410 is in contact with the substrate W on a horizontal plane. That is, the second correction unit 440 may be in contact with a third point on the side end of the substrate W included on an axis parallel to X-axis, at which the first correction unit 410 is in contact with the substrate W on the horizontal plane, and may include a second contact portion 441 (see FIG. 3) in contact with the third point on the side end of the substrate W. For example, when viewed from above, the third point may refer to a lowermost point of the substrate W.

The second correction unit 440 may include a second contact portion 441, a second drive unit 442, a body 443, a guide rail (not illustrated), an elastic portion 445, and a displacement measurement unit 446.

The second contact portion 441 may be in contact with the third point on the side end of the substrate W. In addition, the second contact portion 441 may be formed of a material the same as PEEK filled with carbon. The second contact portion 441 may be coupled to the second drive unit 442.

The second drive unit 442 may change a position of the second contact portion 441. The second drive unit 442 may be one of known linear motors.

The elastic portion 445 may be disposed between the other surface of the second drive unit 442 and the body 443. More specifically, one end of the elastic portion 445 may be coupled to the other surface of the second drive unit 442, and the other end of the elastic portion 445 may be coupled to the body 443, opposing the other surface of the second drive unit 442. The other surface of the second drive unit 442 may be a surface, opposing one surface of the second drive unit 442 to which the second contact portion 441 is coupled. According to an example embodiment, the elastic portion 445 may include a spring having elastic force. Accordingly, the elastic portion 445 may provide elastic force in a direction of movement (for example, second direction 4) of the second contact portion 441. In addition, the elastic portion 445 may be designed to have an elastic modulus, causing damage to the substrate W, when the second correction unit 440 is in contact with the third point on the side end of the substrate W.

The displacement measurement unit 446 may measure displacement of the second drive unit 442. The displacement measurement unit 446 according to an example embodiment may be a proximity sensor, oscillating a predetermined wavelength toward a target object and receiving a wavelength reflected from the target object to measure a distance to the target object. The target object according to an example embodiment may be the second drive unit 442. The displacement measurement unit 446 may be disposed on an upper surface of the body 443. According to an example embodiment, the displacement measurement unit 446 may be disposed at an upper end of the body 443.

A displacement value of the second drive unit 442 may be measured with respect to a plurality of points on the side end of the substrate W. While the chuck 331 rotates the substrate W, a displacement value of the second drive unit 442 may be measured using the displacement measurement unit 466 at the plurality of points, for example, a first measurement point P1, a second measurement point P2, a third measurement point P3, and a fourth measurement point P4, and eccentricity of the substrate W may be measured based on information on a plurality of displacement values for respective points. In an example embodiment, the first measurement point P1, the second measurement point P2, the third measurement point P3, and the fourth measurement point P4 may be disposed at an interval of 90 degrees with respect to a center of the substrate W.

For example, a displacement difference of 40 micrometers may occur at the first measurement point P1, as compared to a normal state, and a displacement difference of 40 micrometers may occur at the third measurement point P3, as compared to the normal state. In this case, a center C′ of the substrate W to be treated may be determined to be eccentric downwardly by 20 micrometers from a center C of the chuck 331 on a Y-axis.

The storage unit 110 may store an amount of eccentricity correction corrected by the eccentricity correction unit 400, and an amount of misalignment of the support unit 330, including the chuck 331, calculated by adding the amount of eccentricity correction and a degree of corrected eccentricity of the substrate W.

A degree to which the substrate W deviates from a correct position thereof may be a degree of substrate eccentricity, and an amount of substrate position movement, performed by the eccentricity correction unit 400 depending on the degree of substrate eccentricity, may be the amount of eccentricity correction. The degree of substrate eccentricity and the amount of eccentricity correction may be the same or different from each other. Even when the degree of substrate eccentricity and the amount of eccentricity correction are different from each other, when the degree of substrate eccentricity is within an allowable eccentricity value, substrate treatment may be performed assuming that the substrate W is in the correct position. An allowable amount of eccentricity correction may be an amount of the eccentricity correction unit 400 being moved to correct eccentricity of the substrate W. Any further movement may cause other errors or inaccuracies even when the substrate W is in the correct position, and thus may be set to be unallowable.

The amount of misalignment of the support unit 330 may refer to misalignment occurring when the chuck 331 deviates from a correct position thereof or is tilted, when the spin axis 334 is tilted, when the axis driver 335 is not driven at a constant speed and vibrates, or the like.

The storage 110 may store the degree of substrate eccentricity and the amount of eccentricity correction measured by the first correction unit 410 and the second correction unit 440, and may calculate the amount of misalignment of the support unit 330 using the degree of corrected eccentricity of the substrate and amount of eccentricity correction.

The control unit 120 may monitor performance degradation of the eccentricity correction unit 400, based on an amount of change over time in the amount of eccentricity correction of the substrate W stored in the storage unit 110 or the amount of misalignment of the support unit 330, and may control the substrate treatment apparatus depending on a monitoring result.

The control unit 120 may interlock the process chamber 300 when the calculated amount of misalignment is greater than or equal to a preset allowable amount of misalignment or when the amount of eccentricity correction is greater than or equal to the allowable amount of eccentricity correction. When the amount of misalignment of the support unit 330 or the degree of eccentricity of the substrate W exceeds an allowable value, the substrate W may not be disposed in a correct position thereof or may need to perform excessive position movement even through correction of the eccentricity correction unit 400. In this case, the yield of the substrate W may be affected, and thus operations of components of the process chamber 300 may be stopped such that a process is no longer performed.

In addition, when the calculated amount of misalignment is greater than or equal to the preset allowable amount of misalignment or the amount of eccentricity correction is not greater than the allowable amount of eccentricity correction, the control unit 120 may identify a cause of performance degradation of the eccentricity correction unit 400 or a position of the cause depending on a degree of change over time in the amount of eccentricity correction of the substrate W or the amount of misalignment of the support unit 330, or a direction of eccentricity correction. The cause of the performance deterioration may include wear of the contact portions 422, 432, and 441 being in contact with the substrate W to secure the substrate W, or shaking of the support unit 330. Details thereof will be described below.

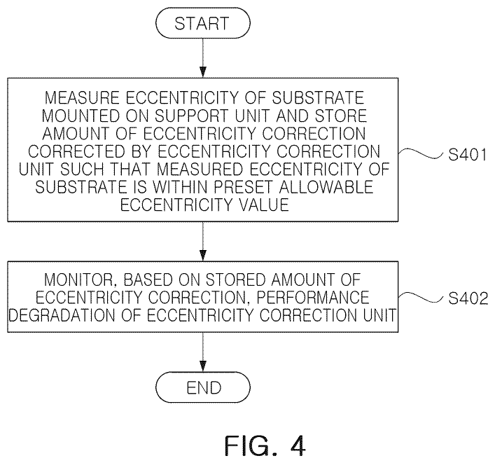

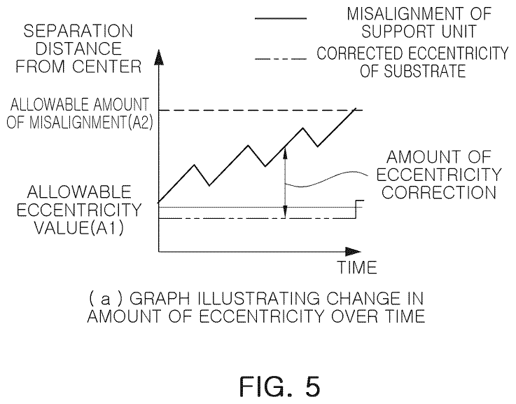

FIG. 4 is a flowchart illustrating a method for monitoring performance of an eccentricity correction unit 400 according to an example embodiment of the present disclosure. Hereinafter, a specific example embodiment of a method for monitoring performance of the eccentricity correction unit 400 will be described with reference to FIGS. 5 to 8.

The method for monitoring performance of the eccentricity correction unit 400 according to an example embodiment of the present disclosure may include an operation (S401) of measuring eccentricity of a substrate W mounted on a support unit 330 and storing an amount of eccentricity correction corrected by the eccentricity correction unit 400 such that measured eccentricity of the substrate is within a preset allowable eccentricity value A1, and an operation (S402) of monitoring, based on the stored amount of eccentricity correction, performance degradation of the eccentricity correction unit 400.

In addition, the method may further include an operation (S403) of providing a user with a repair point in time of the eccentricity correction unit 400 or the support unit 330 predicted using monitored performance degradation of the eccentricity correction unit 400.

The operation (S402) according to an example embodiment may further include an of monitoring an amount of eccentricity correction over time, and determining that performance of the eccentricity correction unit is degraded and operating an interlock, when the amount of eccentricity correction is greater than or equal to an allowable amount of eccentricity correction. Eccentricity correction failure of the eccentricity correction unit 400 may be monitored to prevent performance degradation of a substrate treatment apparatus due to eccentricity correction failure.

Alternatively, the operation (S401) according to an example embodiment may further include an operation of calculating an amount of misalignment of the support unit 330 by adding the amount of eccentricity correction and a degree of corrected eccentricity of the substrate, and storing the calculated amount of misalignment.

For example, even when the substrate W is disposed in a correct position thereof, a center C′ of the substrate W may continue to deviate from the correct position when a center C of the support unit 330 itself is misaligned.

Accordingly, the eccentricity correction unit 400 according to an example embodiment of the present disclosure may rotate the substrate W at a predetermined angle on a horizontal plane to measure and store amounts of eccentricity correction in both a direction, parallel to one axis, and a direction, perpendicular to the one axis, on the horizontal plane.

In other words, eccentricity correction may be performed with respect to both an X-axis and a Y-axis, such that eccentricity of the substrate W may be corrected in addition to misalignment of the support unit 330.

As illustrated in FIG. 5, when eccentricity of the substrate W occurs even when the center C′ of the substrate W is disposed in the correct position, an amount of misalignment of the support unit 330 over time may be calculated by adding the degree of corrected eccentricity of the substrate W and the amount of eccentricity correction over time stored in the storage unit 110.

When the eccentricity correction unit 400 moves excessively for eccentricity correction, an error may be highly likely to occur even when the substrate W is disposed in the correct position. Accordingly, an allowable amount of eccentricity correction of the eccentricity correction unit 400 may be set. When eccentricity of the substrate W is corrected in excess of the allowable amount of eccentricity correction, eccentricity of the substrate W may exceed an allowable eccentricity value A1 or the support unit 330 may exceed an allowable amount of misalignment A2.

The operation (S402) according to an example embodiment may further include an operation of monitoring a degree of change over time in the amount of eccentricity correction of the substrate W or an amount of misalignment of the support unit 330, and determining that performance of the eccentricity correction unit 400 is degraded and operating an interlock, when the calculated amount of misalignment is greater than or equal to a preset allowable amount of misalignment A2.

In other words, whether the calculated amount of misalignment of the support unit 330 reaches the allowable amount of misalignment A2 or more may be monitored. When the calculated amount of misalignment of the support unit 330 reaches the allowable amount of misalignment A2, it may be determined that eccentricity of the substrate W is not corrected within the allowable eccentricity value A1, and a process chamber 300 may be interlocked. The eccentricity correction unit 400 according to an example embodiment of the present disclosure may perform hardware inspection as well as inspection of eccentricity of the substrate W.

The operation (S402) according to an example embodiment, the cause of performance degradation of the eccentricity correction unit 400 may include an operation of identifying a cause of performance degradation of the eccentricity correction unit 400 depending on a degree of change over time in the amount of eccentricity correction of the substrate W or the amount of misalignment of the support unit 330, or may include an operation of determining the cause of performance degradation of the eccentricity correction unit 400 depending on a direction of eccentricity correction.

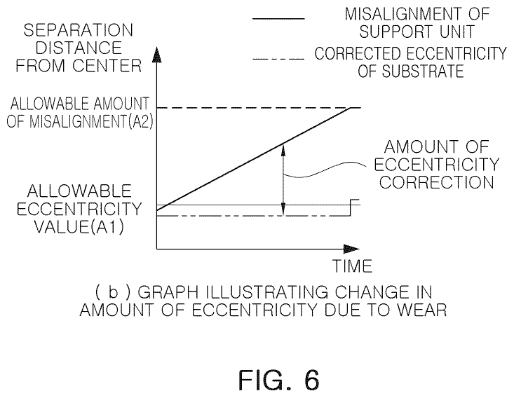

As illustrated in FIG. 6, when the amount of eccentricity correction of the substrate W or the amount of misalignment of the support unit 330 increases at a constant rate over time, the cause of the performance decrease may be wear of contact portions 422, 434, and 441 being in contact with the substrate W to secure the substrate W.

Surfaces of a first-first contact portion 422, a first-second contact portion 434, and a second contact portion 441 in contact with the substrate W may be formed of a material such as PEEK filled with carbon. The PEEK material may have a soft texture such that the substrate W is not damaged due to contact with the substrate W, and thus wear by contact may easily occur.

When the amount of eccentricity correction of the substrate W or the amount of misalignment of the support unit 330 exhibits a tendency to steadily increase over time, the control unit 120 according to an example embodiment may interlock the process chamber 300 and provide, to a user, an alarm message indicating that it is necessary to replace the first-first contact portion 422, the first-second contact portion 434, and the second contact portion 441, when the calculated amount of misalignment is greater than the preset allowable amount of misalignment A2.

For example, when the amount of eccentricity correction is formed in a negative direction from a second direction 4, it may be determined that the substrate W is eccentric upwardly due to wear of the first-first contact portion 422 and the first-second contact portion 434, and the first-first contact portion 422 and the first-second contact portion 434 may be replaced.

In addition, when the amount of eccentricity correction is formed in a positive direction from the second direction 4, it may be determined that the substrate W is eccentric downward due to wear of the second contact portion 441, and the second contact portion 441 may be replaced.

In other words, a component, causing performance degradation of the eccentricity correction unit 400, may be identified depending on the direction of eccentricity correction.

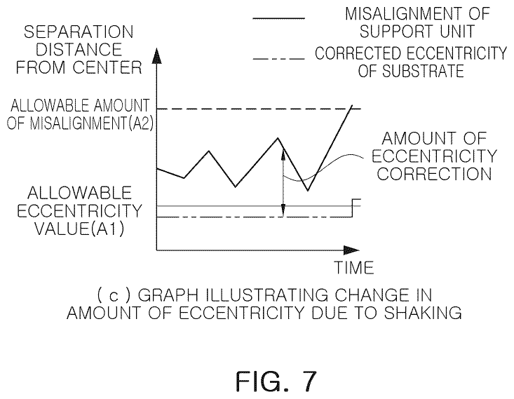

Alternatively, as illustrated in FIG. 7, when the amount of eccentricity correction of the substrate W or the amount of misalignment of the support unit 330 has a continuously changed direction in a vibrating manner without having constant directionality over time, the cause of the performance degradation may be shaking of the support unit 330.

For example, when a chuck 331, a spin axis 334, or an axis driver 335 is not properly secured and shakes in position, shaking may continue to worsen when an appropriate measure is not taken.

When the amount of eccentricity correction of the substrate W or the amount of misalignment of the support unit 330 has a continuously changed direction in a vibrating manner without having constant directionality over time, the cause may be identified as shaking, and a position in which shaking occurs may be identified based on the amount of eccentricity correction or the amount of misalignment of the support unit 330 depending on a degree of shaking, and the position may be provided to a user through an alarm message.

In other words, the control unit 120 may identify a cause of occurrence of eccentricity and a position in which eccentricity occurs depending on a change over time in the amount of eccentricity correction of the substrate W or the amount of misalignment of the support unit 330, and may provide the cause and the position to the user through the alarm message. In addition, a repair point in time of the eccentricity correction unit 400 or the support unit 330, predicted using monitored performance degradation of the eccentricity correction unit 400, may be provided to the user.

According to an example embodiment, the operation (S401) may include an operation of rotating the substrate W at a predetermined angle on a horizontal plane to measure and store amounts of eccentricity correction in both a direction, parallel to one axis, and a direction, perpendicular to the one axis, on the horizontal plane. The operation (S402) may include an operation of identifying a cause of performance degradation of the eccentricity correction unit 400 depending on a direction of eccentricity correction, among the direction, parallel to the one axis, and the direction, perpendicular to the one axis, on the horizontal plane. Here, the cause of performance degradation may include a position of a component in which performance degradation occurs.

Eccentricity correction of the substrate W may be performed with respect to both an X-axis and a Y-axis, thereby correcting not only eccentricity of the substrate W but also misalignment of the support unit 330, and identifying a position in which performance degradation of the eccentricity correction unit 400 occurs, depending on a direction of eccentricity correction with respect to each axis.

The operation (S401) may further include an operation of treating the substrate W without performing, by the eccentricity correction unit 400, eccentricity correction, when the amount of misalignment of the support unit 330 is present and eccentricity of the substrate is within the preset allowable eccentricity value A1.

Eccentricity correction of the substrate W may be performed with respect to both the X-axis and the Y-axis, and thus an allowable eccentricity value A1 may be set with respect to a position of the substrate W. When eccentricity of the substrate W is within the allowable eccentricity value A1, no eccentricity correction may be performed even when misalignment of the support unit 330 or eccentricity of the substrate W is present.

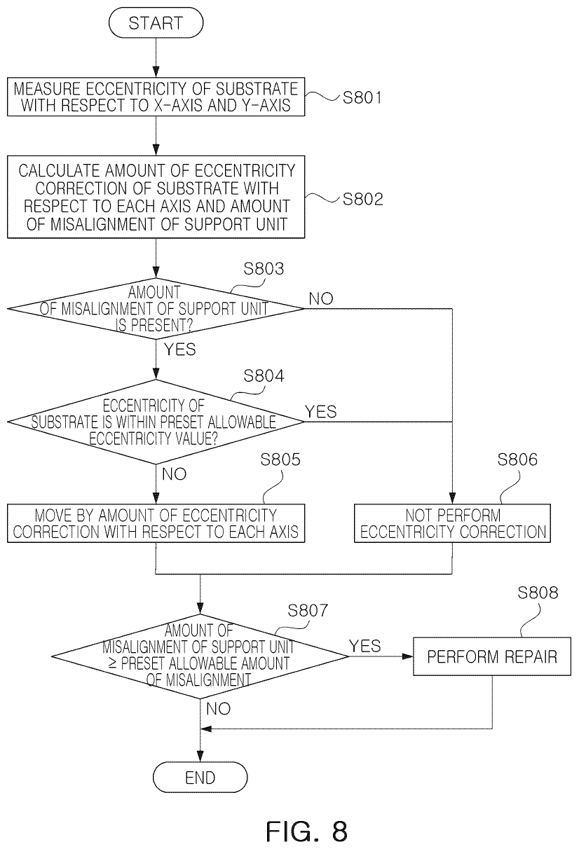

Specifically, as illustrated in FIG. 8, eccentricity of a substrate W with respect to an X-axis and a Y-axis may be measured (S801), and an amount of eccentricity correction of the substrate W and an amount of misalignment of a support unit 330 with respect to each axis may be calculated (S802).

In an example embodiment, the amount of misalignment of the support unit 330 is present (“YES” in S803) and eccentricity of the substrate W is within the preset allowable eccentricity value A1 (“YES” in S804), or the amount of misalignment of the support unit 330 is not present (“NO” in S803), eccentricity correction may not be performed (S806).

In an example embodiment, when the amount of misalignment of the support unit 330 is present (“YES” in S803) and eccentricity of the substrate W is not within the preset allowable eccentricity value A1 (“NO” in S804), the eccentricity correction unit 400 may be moved by the amount of eccentricity correction with respect to each axis (S805).

Subsequently, when the amount of misalignment of the support unit 330 is greater than a preset allowable amount of misalignment A2 (“YES” in S807), the control unit 120 may provide, to a user, an alarm message indicating that a repair point in time has been reached, such that repair may be performed (S808).

Subsequently, when the amount of misalignment of the support unit 330 is less than the preset allowable amount of misalignment A2 (“NO” in S807), eccentricity correction of the substrate W may be completed and a substrate treating process may be performed.

Accordingly, the substrate treatment apparatus according to an example embodiment of the present disclosure may include a support unit 330 supporting a substrate W, a liquid supply unit 340 supplying liquid to the substrate W supported by the support unit 330, a treatment container 320 surrounding the substrate W supported by the support unit 330, an eccentricity correction unit 400 measuring and correcting eccentricity of the substrate W supported by the support unit 330, a storage unit 110 storing an amount of eccentricity correction corrected by the eccentricity correction unit 400, and a control unit 120 monitoring, based on the stored amount of eccentricity correction, performance degradation of the eccentricity correction unit 400 and controlling the substrate treatment apparatus depending on a monitoring result.

The storage unit 110 may store an amount of misalignment of the support unit 330 calculated by adding the amount of eccentricity correction and a degree of corrected eccentricity of the substrate W.

The control unit 120 may interlock the substrate treatment apparatus, when the calculated amount of misalignment is greater than or equal to a preset allowable amount of misalignment, or when the amount of eccentricity correction is greater than or equal to an allowable amount of eccentricity correction.

In addition, when the substrate treatment apparatus is interlocked, a cause of performance degradation of the eccentricity correction unit 400 or a position in which the cause of performance degradation occurs may be identified depending on a degree of change over time in the amount of eccentricity correction of the substrate W or the amount of misalignment of the support unit 330.

The eccentricity correction unit 400 according to an example embodiment may rotate the substrate W at a predetermined angle on a horizontal plane to measure amounts of eccentricity correction in both a direction, parallel to one axis, and a direction, perpendicular to the one axis, on the horizontal plane, and may move the substrate W by an amount of eccentricity correction in each of the directions. That is, correction may be performed with respect to both an X-axis and a Y-axis, such that the amount of eccentricity correction of the substrate W or the amount of misalignment of the support unit 330 may be corrected at once.

In addition, when the amount of misalignment of the support unit 330 is present and eccentricity of the substrate W is within a preset allowable eccentricity value, the eccentricity correction unit 400 may not move the substrate W by an amount of eccentricity correction corresponding to eccentricity of the substrate W. That is, that's because a certain allowable eccentricity value may be set due to correction that may be performed with respect to both the X-axis and the Y-axis.

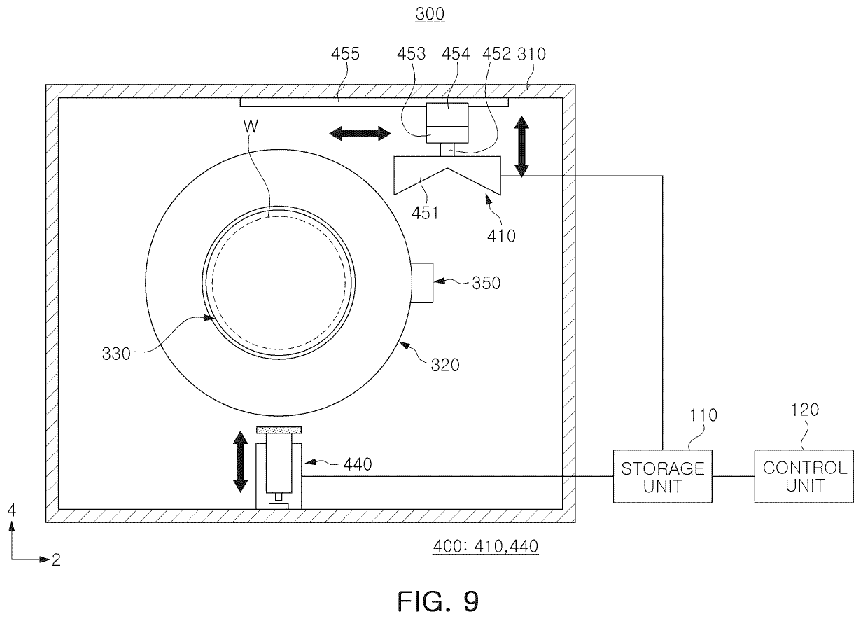

FIG. 9 is a top cross-sectional view of a process chamber 300 in which an eccentricity correction unit 400 is installed according to another example embodiment of the present disclosure.

A first correction unit 410 may include a first contact portion 451, a first arm 452, first drive units 453 and 454, and a first rail 455.

The first arm 452 may have a structure substantially the same or similar to that of the above-described first arm 424, and the first rail 455 may have a structure substantially the same or similar to that of the above-described first rail 428, and thus a description thereof will be omitted.

The first contact portion 451 may be in contact with a plurality of points on a side end of the substrate W to change a position of the substrate W. More specifically, the first contact portion 451 may be in contact with two points on the side end of the substrate W. One surface of the first contact portion 451 may have a substantially “V” shape, when viewed from above. The one surface of the first contact portion 451, having a “V” shape, may be in contact with the substrate W. In addition, the one surface of the first contact portion 451 may be formed of a material the same as PEEK filled with carbon, thereby minimizing impacts applied to the substrate W when being in contact with the substrate W.

The first drive units 453 and 454 may move the first contact portion 451 in a first direction 2 and a second direction 4. The first drive units 453 and 454 may include a plurality of motors. A motor 453 of one of the first drive units 453 and 454 may move the first contact portion 451 in a direction, parallel to the first direction 2, and a motor 454 of one of the first drive units 453 and 454 may move the first contact portion 451 in a direction, parallel to the second direction 4.

The storage unit 110 and the control unit 120 may also be applied to the eccentricity correction unit 400 according to another example embodiment of the present disclosure to monitor performance degradation of the eccentricity correction unit 400 and control a substrate treatment apparatus accordingly. A repeated description will be omitted.

In the description of the example embodiment, “ . . . portion” or “ . . . unit” may be implemented in various manners, for example, a processor, program instructions executed by the processor, software module, microcode, computer program product, logic circuit, application-specific integration circuitry, firmware, and the like.

The method disclosed in the example embodiments may be directly implemented by a hardware processor, or may be implemented and completed by a combination of a hardware module and a software module among processors. The software module may be stored in conventional storage media such as random access memory (RAM), flash memory, read-only memory (ROM), programmable ROM or electrically erasable programmable memory, register, or the like. The storage medium may be disposed in a memory, and the processor may read information stored in the memory and may combine with the hardware to complete the above-described method. A repeated description will be omitted herein.

In an implementation process, the method may be completed through an integrated logic circuit of hardware in the processor or an instruction in the form of software. The method described in combination with the example embodiment of the present disclosure may be directly implemented as being executed by a hardware processor, or being executed by a combination of hardware and software modules in the processor. The software module may be stored in a conventional storage medium such as RAM, flash memory, ROM, programmable ROM or electrically erasable programmable memory, a register, or the like. The storage medium may be positioned in the memory, and the processor may read information in the memory and complete the method in combination with the hardware thereof.

That is, a person skilled in the art may be aware that the units and algorithm steps in the examples described with reference to the example embodiments described herein may be implemented by electronic hardware or a combination of computer software and electronic hardware. Whether such functions are performed by hardware or software depends on particular applications and design constraints of the technical solutions. A person skilled in the art may use different methods to implement the above-described functions for each particular application, but it should not be considered that the implementation goes beyond the scope of the disclosure.

In some example embodiments provided in the present application, it should be understood that the device and method described herein may be implemented in other manners. For example, the above-described device example embodiment is merely an example. For example, division of the units is merely division of logical functions, and may be other division in actual implementation. For example, a plurality of units or components may be combined or integrated into another system, or some components may be ignored or may not be performed. In addition, mutual couplings, direct couplings, or communication connections displayed or discussed may be indirect couplings or communication connections implemented using some interfaces, devices or units, and may be implemented in electrical, mechanical, or other form.

The units described above as separate parts may be physically separated from each other, and parts displayed as units may be or may not be physical units. Thus, the parts may be disposed in one position, or may be distributed on a plurality of network units. Some or all of the units may be selected based on actual requirements to achieve aspects of the present disclosure.

That is, functional in units the example embodiments of the present disclosure may be integrated into one processing unit, or each of the units may be present solely, or two or more units are integrated into one unit.

When the functions are implemented in a form of a software functional unit and are sold or used as an independent product, the functions may be stored in a non-transitory computer-readable storage medium. Based on such an understanding, the technical solution of the present application, in essence, or the part contributing to the related technology or the part of the technical solution may be implemented in the form of a software product, and the computer software product is stored in a storage medium and includes several instructions for enabling a computer device (which may be a personal computer, a server, or a network device, or the like) to perform all or part of the steps described in methods in the example embodiments of the present disclosure. The above-described storage medium includes various media capable of storing program codes, such as a U disk, a mobile hard disk, a ROM, a RAM, a magnetic disk, or an optical disk.

While example embodiments have been illustrated and described above, it will be apparent to those skilled in the art that modifications and variations could be made without departing from the scope of the present disclosure as defined by the appended claims.

What is claimed is:

1. A method for monitoring performance of an eccentricity correction unit, the method comprising:
a first operation of measuring eccentricity of a substrate mounted on a support unit and storing an amount of eccentricity correction corrected by the eccentricity correction unit such that measured eccentricity of the substrate is within a preset allowable eccentricity value; and
a second operation of monitoring, based on the stored amount of eccentricity correction, performance degradation of the eccentricity correction unit.

2. The method of claim 1, wherein the first operation further includes an operation of calculating an amount of misalignment of the support unit by adding the amount of eccentricity correction and a degree of corrected eccentricity of the substrate, and storing the calculated amount of misalignment.

3. The method of claim 2, wherein the second operation further includes an operation of determining that performance of the eccentricity correction unit is degraded and operating an interlock, when the calculated amount of misalignment is greater than or equal to a preset allowable amount of misalignment.

4. The method of claim 1, wherein the second operation further includes an operation of determining that performance of the eccentricity correction unit is degraded and operating an interlock, when the amount of eccentricity correction is greater than or equal to an allowable amount of eccentricity correction.

5. The method of claim 2, wherein the second operation includes an operation of identifying a cause of performance degradation of the eccentricity correction unit depending on a degree of change over time in the amount of eccentricity correction of the substrate or the amount of misalignment of the support unit.

6. The method of claim 5, wherein the cause of performance degradation includes wear of a contact portion being in contact with the substrate to secure the substrate, or shaking of the support unit.

7. The method of claim 2, wherein the second operation includes an operation of identifying a cause of performance degradation of the eccentricity correction unit depending on a direction of eccentricity correction.

8. The method of claim 2, wherein the first operation includes an operation of rotating the substrate at a predetermined angle on a horizontal plane to measure and store amounts of eccentricity correction in both a direction, parallel to one axis, and a direction, perpendicular to the one axis, on the horizontal plane.

9. The method of claim 8, wherein the second operation includes an operation of identifying a cause of performance degradation of the eccentricity correction unit depending on a direction of eccentricity correction, among the direction, parallel to the one axis, and the direction, perpendicular to the one axis, on the horizontal plane.

10. The method of claim 1, wherein the first operation further includes an operation of treating the substrate without performing, by the eccentricity correction unit, eccentricity correction, when an amount of misalignment of the support unit is present and eccentricity of the substrate is within the preset allowable eccentricity value.

11. The method of claim 1, further comprising:
a third operation of providing a user with a repair point in time of the eccentricity correction unit or the support unit predicted using monitored performance degradation of the eccentricity correction unit.

12. A substrate treatment apparatus comprising:
a support unit configured to support a substrate;
a liquid supply unit configured to supply liquid to the substrate supported by the support unit;
a treatment container configured to surround the substrate supported by the support unit;
an eccentricity correction unit configured to measure and correct eccentricity of the substrate supported by the support unit;
a storage unit configured to store an amount of eccentricity correction corrected by the eccentricity correction unit; and
a control unit configured to monitor, based on the stored amount of eccentricity correction, performance degradation of the eccentricity correction unit, and to control the substrate treatment apparatus depending on a monitoring result.

13. The substrate treatment apparatus of claim 12, wherein the storage unit is configured to store an amount of misalignment of the support unit calculated by adding the amount of eccentricity correction and a degree of corrected eccentricity of the substrate.

14. The substrate treatment apparatus of claim 13, wherein the control unit is configured to interlock the substrate treatment apparatus, when the calculated amount of misalignment is greater than or equal to a preset allowable amount of misalignment.

15. The substrate treatment apparatus of claim 12, wherein the control unit is configured to interlock the substrate treatment apparatus, when the amount of eccentricity correction is greater than or equal to an allowable amount of eccentricity correction.

16. The substrate treatment apparatus of claim 13, wherein
the control unit is configured to identify a cause of performance degradation of the eccentricity correction unit depending on a degree of change over time in the amount of eccentricity correction of the substrate or the amount of misalignment of the support unit, or a direction of eccentricity correction, and
the cause of the performance degradation includes wear of a contact portion being in contact with the substrate to secure the substrate, or shaking of the support unit.

17. The substrate treatment apparatus of claim 12, wherein the eccentricity correction unit is configured to:
rotate the substrate at a predetermined angle on a horizontal plane to measure amounts of eccentricity correction in both a direction, parallel to one axis, and a direction, perpendicular to the one axis, on the horizontal plane; and
move the substrate by an amount of eccentricity correction in each of the directions.

18. The substrate treatment apparatus of claim 13, wherein the eccentricity correction unit is configured not to move the substrate by an amount of eccentricity correction corresponding to eccentricity of the substrate, when an amount of misalignment of the support unit is present and eccentricity of the substrate is within a preset allowable eccentricity value.

19. A substrate treatment apparatus comprising:
a housing having an internal space;
a chuck positioned in the internal space, the chuck configured to support and rotate a substrate;
a liquid supply unit configured to supply liquid to the substrate supported by the chuck to etch an edge region of the substrate;
a treatment container configured to surround the substrate supported by the chuck;
an elevation unit configured to raise and lower the treatment container;
an eccentricity correction unit in contact with a plurality of points of a side end of the substrate supported by the chuck, the eccentricity correction unit configured to correct eccentricity of the substrate supported by the chuck;
a storage unit configured to store an amount of eccentricity correction corrected by the eccentricity correction unit, and an amount of misalignment of the support unit calculated by adding the amount of eccentricity correction and a degree of corrected eccentricity of the substrate; and
a control unit configured to monitor, based on an amount of change over time in the stored amount of eccentricity correction or amount of misalignment, performance degradation of the eccentricity correction unit, and to control the substrate treatment apparatus depending on a monitoring result,
wherein the eccentricity correction unit includes:
a first correction unit in contact with one point and another point, sharing one axis on a horizontal plane, among the points; and
a second correction unit in contact with still another point belonging to another axis, different from the one axis,
the second correction unit includes:
a displacement measurement unit configured to measure a degree of eccentricity at different points of the rotating substrate; and
an elastic portion in contact with the side ends of the substrate, the elastic portion configured to provide elastic force, and
the control unit is configured to interlock the substrate treatment apparatus, when the calculated amount of misalignment is greater than or equal to a preset allowable amount 4 misalignment or the amount of eccentricity correction is greater than or equal to an allowable amount of eccentricity correction.

20. The substrate treatment apparatus of claim 19, wherein the eccentricity correction unit is configured not to move the substrate by an amount of eccentricity correction corresponding to eccentricity of the substrate, when an amount of misalignment of the support unit is present and eccentricity of the substrate is within a preset allowable eccentricity value.
